(19) United States
(12) Patent Application Publication
(10) Pub. No.: US 2015/0098271 A1
(43) Pub. Date: Apr. 9, 2015

(54) SYSTEM AND METHOD OF STORING DATA IN A DATA STORAGE DEVICE

(71) Applicant: SANDISK TECHNOLOGIES INC., PLANO, TX (US)

(72) Inventor: MENAHEM LASSER, KOHAV-YAIR (IL)

(73) Assignee: SANDISK TECHNOLOGIES INC., PLANO, TX (US)

(21) Appl. No.: 14/049,587

(22) Filed: Oct. 9, 2013

(51) Int. Cl. G11C 16/10

(52) U.S. Cl. CPC G11C 16/107
USPC 365/185.11

(57) ABSTRACT

A method that may be performed in a data storage device includes selecting a writing order for data to be written to a set of word lines of a block of a non-volatile memory. The data is organized in pages that are ordered according to a logical page address order. The writing order is selected from at least a first order or a second order that is distinct from the first order. Stored data in the non-volatile memory written according to the first order has logical page addresses that decrease with increasing values of word line physical addresses. The method also includes writing the data to the set of word lines according to the selected writing order and storing a flag value that indicates the selected writing order.

### FIELD OF THE DISCLOSURE

The present disclosure is generally related to writing data to a memory in a data storage device.

### BACKGROUND

Non-volatile data storage devices, such as universal serial bus (USB) flash memory devices or removable storage cards, have allowed for increased portability of data and software applications. Flash memory devices can enhance data storage density by storing multiple bits in each flash memory cell. For example, Multi-Level Cell (MLC) flash memory devices provide increased storage density by storing 3 bits per cell, 4 bits per cell, or more. Although increasing the number of bits per cell and reducing device feature dimensions may increase a storage density of a memory device, a bit error rate of data stored at the memory device may also increase.

A cross-coupling effect from an upper neighbor cell to a particular cell of a non-volatile memory that is being read causes a shifting of the particular cell's threshold voltage. The amount of the shifting depends on the state programmed into the upper neighbor cell. For example, if a higher voltage value is programmed into the upper neighbor cell, the amount of shifting is also higher. Differential Look Ahead (DLA) is a reading mode that provides a countermeasure against the shifting. In the DLA reading mode, a next word line is read and the data of the next word line is used to offset the cross-coupling effect. Reading using the DLA mode is useful for applications that require high reliability and for high density memory devices. While reading in the DLA mode may provide a countermeasure to the cross-coupling effect and shifting, reading with the DLA mode may have increased latency due to extra operations performed (e.g. extra reading operations and computations).

### SUMMARY

Data that includes pages having sequential logical addresses can be re-ordered when stored at a non-volatile memory. Re-ordering the data enables sequentially read pages (e.g., pages requested and retrieved in logical address order) to be read by sensing word lines having higher physical addresses prior to sensing word lines having lower physical addresses. Data sensed from higher-addressed word lines may be used to improve sensing accuracy of neighboring lower-addressed word lines using differential look ahead read operations.

A flag may be stored for each block that indicates whether data stored in the block is written using a first order (e.g., re-ordered from a sequential logical address order) or a second order (e.g., in the sequential logical address order). If write order selection is performed at a sub-block granularity, multiple flags may be stored for each block to indicate a writing order of the data stored in each portion of the block.

### BRIEF DESCRIPTION OF THE DRAWINGS

FIG. 1 is a block diagram of a particular illustrative embodiment of a system including a data storage device configured to store data so that logical page addresses of the data decrease with increasing values of word line physical addresses;

FIG. 2 is a block diagram of a particular embodiments of blocks and write order indicators corresponding to the blocks that may be included in the data storage device of FIG. 1;

FIG. 3 is a flowchart of a first particular embodiment of a method of storing data;

FIG. 4 is a flowchart of a second particular embodiment of a method of storing data;

FIG. 5 is a flowchart of a third particular embodiment of a method of storing data; and

FIG. 6 is a flowchart of a fourth particular embodiment of a method of storing data.

### DETAILED DESCRIPTION

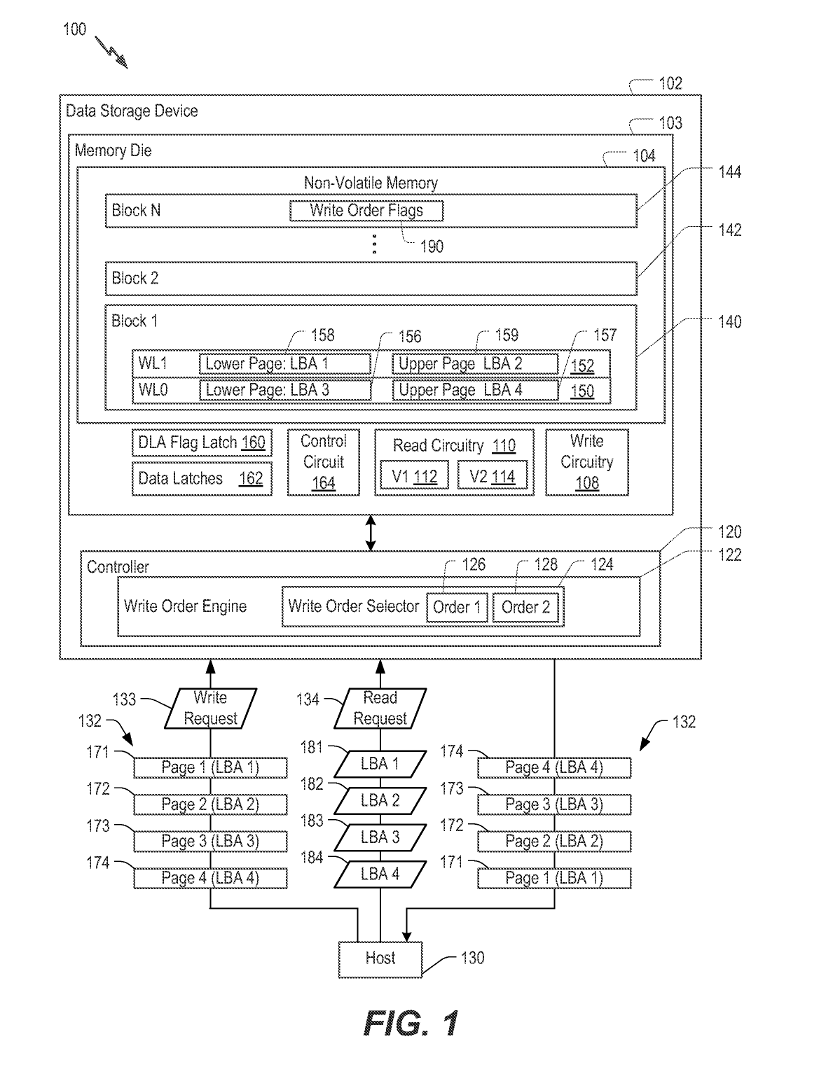

Referring to FIG. 1, a particular embodiment of a system 100 includes a data storage device 102 coupled to a host device 130. The data storage device 102 is configured to store data according to a writing order that results in logical page addresses of the data decreasing with increasing values of word line physical addresses to enhance read efficiency of differential look ahead (DLA) mode read operations.

The host device 130 may be configured to provide data, such as user data 132, to be stored at a non-volatile memory 104 or to request data to be read from the non-volatile memory 104. For example, the host device 130 may include a mobile telephone, a music player, a video player, a gaming console, an electronic book reader, a personal digital assistant (PDA), a computer, such as a laptop computer or notebook computer, any other electronic device, or any combination thereof. The host device 130 communicates via a memory interface that enables reading from the non-volatile memory 104 and writing to the non-volatile memory 104. For example, the host device 130 may operate in compliance with a Joint Electron Devices Engineering Council (JEDEC) industry specification, such as a Universal Flash Storage (UFS) Host Controller Interface specification. As other examples, the host device 130 may operate in compliance with one or more other specifications, such as a Secure Digital (SD) Host Controller specification as an illustrative example. The host device 130 may communicate with the data storage device 102 in accordance with any other suitable communication protocol.

The non-volatile memory 104 may be a non-volatile flash memory, such as a NAND flash memory. The non-volatile memory 104 may include multiple blocks, such as a first block (Block 1) 140, a second block (Block 2) 142, up to an Nth block (Block N) 144. Each block 140-144 includes groups of storage elements, such as a first word line having physical address “0” (WL0) 150 and a second word line having physical address “1” (WL1) 152 of a multi-level cell (MLC) flash memory. Although two word lines (WL0, WL1) are shown, it should be understood that each block 140-144 of the non-volatile memory 104 includes a plurality of word lines and typically includes more than the two illustrated word lines shown. For example, the non-volatile memory 104 may include multiple erase blocks (e.g., 1024 erase blocks), and each erase block may include multiple word lines (e.g., 128 word lines). Each of the word lines includes a lower page and an upper page. For example, the first word line 150 (WL0) includes a lower page 156 and an upper page 157 and the second word line 152 (WL1) includes a lower page 158 and an upper page 159.

The data storage device 102 may be configured to be coupled to the host device 130 as embedded memory, such as eMMC® (trademark of JEDEC Solid State Technology Association, Arlington, Va.) and eSD, as illustrative examples. To illustrate, the data storage device 102 may correspond to an eMMC (embedded MultiMedia Card) device. As another example, the data storage device 102 may be a memory card, such as a Secure Digital SD® card, a microSD® card, a miniSD™ card (trademarks of SD-3C LLC, Wilmington, Del.), a MultiMediaCard™ (MMC™) card (trademark of JEDEC Solid State Technology Association, Arlington, Va.), or a CompactFlash® (CF) card (trademark of SanDisk Corporation, Milpitas, Calif.). The data storage device 102 may operate in compliance with a JEDEC industry specification. For example, the data storage device 102 may operate in compliance with a JEDEC eMMC specification, a JEDEC Universal Flash Storage (UFS) specification, one or more other specifications, or a combination thereof.

The controller 120 is configured to receive data and instructions from and to send data to the host device 130. The controller 120 is further configured to send data and commands to the non-volatile memory 104 and to receive data from the non-volatile memory 104. For example, the controller 120 is configured to send data and a write command to instruct the non-volatile memory 104 to store the data to a specified address. As another example, the controller 120 is configured to send a read command to read data from a specified address of the non-volatile memory 104.

The data storage device 102 includes one or more memory dies, illustrated as a representative memory die 103 that includes the non-volatile memory 104. The memory die 103 also includes a DLA flag latch 160, data latches 162, control circuitry 164, such as a state machine, write circuitry 108, and read circuitry 110. The read circuitry 110 may apply multiple voltages, such as a representative first voltage (V1) 112 and a representative second voltage (V2) 114 to a selected word line.

The controller 120 includes a write order engine 122. The write order engine 122 is configured to determine a writing order for data to be written to a set of word lines of a block of the non-volatile memory 104. For example, the user data 132 may be organized in pages that are ordered according to a logical page address order, including a first page (Page 1) 171 corresponding to a first logical block address (LBA 1) 181, a second page (Page 1) 172 corresponding to a second logical block address (LBA 2) 182 a third page (Page 3) 173 corresponding to a third logical block address (LBA 3) 183, and a fourth page (Page 4) 174 corresponding to a fourth logical block address (LBA 4) 184. The LBAs may be in a sequential logical page address order with the first LBA 181 having the earliest (lowest) address of the LBAs 181-184 in the logical page address order and the fourth LBA 184 having the latest (highest) address of the LBAs 181-184 in the logical page address order.

The write order engine 122 includes a write order selector 124 configured to select the writing order from at least a first order 126 or a second order 128 that is distinct from the first order 126. For example, after storing data using the first order 126 as the selected write order, the logical page addresses of the pages of the stored data decrease with increasing values of word line physical addresses. To illustrate, the user data 132 is stored in WL0 150 and WL1 152 according to the first order 126. WL0 150 stores the third page 173 corresponding to the third LBA 183 and the fourth page 174 corresponding to the fourth LBA 184, and WL1 151 stores the first page 171 corresponding to the first LBA 181 and the second page 172 corresponding to the second LBA 182. Thus, as the word line physical address increases from 0 (i.e., WL0 150) to 1 (i.e., WL1 152), logical page addresses of the stored data decrease from LBA 3 and LBA 4 to LBA 1 and LBA 2.

In contrast to the first order 126, storing data using the second order 128 as the selected write order results in the logical page addresses of the pages of the stored data increasing with increasing values of word line physical addresses. To illustrate, the user data 132 may be stored in WL0 150 and WL1 152 with the first page 171 and the second page 172 in WL0 150, and with the third page 173 and the fourth page 174 in WL1 151. Thus, as the word line physical address increases from 0 (i.e., WL0 150) to 1 (i.e., WL1 152), logical page addresses of the stored data increase from LBA 1 and LBA 2 to LBA 3 and LBA 4.

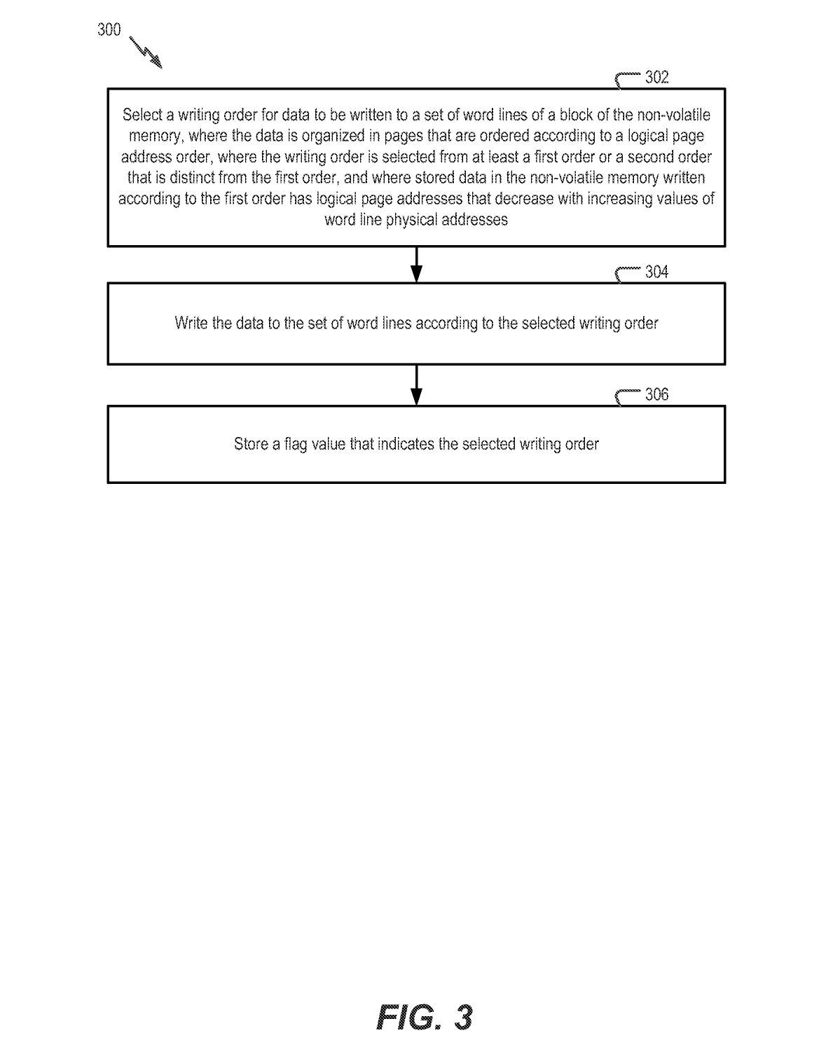

The controller 120 may be configured to instruct the non-volatile memory 104 to write data to a set of word lines according to the selected writing order. Examples of sequences of controller write instructions are provided with respect to Tables 1-3 below. The controller 120 may also be configured to store a flag value that indicates the selected writing order. To illustrate, the non-volatile memory 104 may store a set of write order flags 190. The write order flags 190 may include one or more flags for each block 140-144. A value of each of the write order flags 190 may indicate whether the corresponding block was programmed using the first order 126 (e.g., flag value=0) or the second order 128 (e.g., flag value=1). Although the write order flags 190 are illustrated in the non-volatile memory 104, the controller 120 may copy the write order flags 190 to a controller memory (e.g., a random access memory (RAM)) and update the write order flags 190 at the non-volatile memory 104 for persistent storage while the data storage device 102 is powered off. One or more write order flags may be provided for each block of the non-volatile memory 104, such as described in further detail with respect to FIG. 3.

During a read operation, a first command may be issued by the controller 120 and sent to the memory die 103 to cause DLA reading to be performed to read data from a target word line according to DLA flag data corresponding to states of one or more other storage elements (e.g., flag data indicating, for each storage element, a state of the upper neighbor of that storage element). For example, the controller 120 may send a first command indicating the lower page 156, the upper page 157, or both, to the memory die 103. To illustrate, the controller 120 may send the first command indicating that the lower page 156 is to be read. The control circuitry 164 (e.g., a state machine) at the memory die 103 may be responsive to the first command to initiate a read operation by causing the read circuitry 110 to read the second word line 152 and to load sense data from the second word line 152 to the data latches 162. The control circuitry 164 may further cause one or more logical operations to be performed to the data in the data latches 162 to generate flag data that is copied into the DLA flag latch 160. The control circuitry 164 may cause the read circuitry 110 to read the target word line (e.g., the lower page 156) according to a DLA mode by selecting, for each storage element of the first word line 150, results from reading the first word line 150 while applying a first voltage 112 to the second word line 152 or results from reading the first word line 150 while applying a second voltage 114 to the second word line 152. The selection may be based on a corresponding bit in the data in the DLA flag latch 160. The control circuitry 164 may be configured to cause results from reading the first word line 150 to be sent to the controller 120.

Because reading each word line in the DLA mode uses DLA flag data that is based on data stored at the neighboring word line having the next highest word line physical address, ordering data according to the first order 126 may improve DLA efficiency when the data is requested as sequential LBAs. Each requested page of data may be used to populate DLA flag data for the next word line to be read. The controller 120 may send commands to the memory die 103 to cause DLA reading to be performed to read data from a target word line using existing flag data that is in the DLA flag latch 160 when the target word line is read. In this case, the next word line that neighbors the target word line has already been read and used to populate the DLA flag latch 160 and therefore is not read again in response to the command to read the target word line.

For example, the controller 120 may send a command indicating the lower page 156, the upper page 157, or both, to the memory die 103. To illustrate, the controller 120 may send the command indicating that the upper page 157 is to be read using the current flag data. The control circuitry 164 at the memory die 103 may be responsive to the command to cause the read circuitry 110 to read the target word line (e.g., the upper page 157) according to a DLA mode. The control circuitry 164 may cause the read circuitry 110 to select, for each storage element of the first word line 150, read results corresponding to applying one of the first voltage 112 or the second voltage 114 to the second word line 152 based on a corresponding bit in the data in the DLA flag latch 160 while reading data from the first word line 150. The control circuitry 164 may be configured to populate the DLA flag latch 160 based on data in the data latches 162 and to cause results from reading the first word line 150 to be sent to the controller 120.

For DLA reading of the first word line 150, flag data may be generated based on the data read from the second word line 152. The data read from the second word line 152 may already be in the data latches 162. For example, in a 2 bit-per-cell (BPC) implementation where storage element states correspond to “11” (erase state), “10” (state A), “00” (state B), or “01” (state C), where “xy” indicates an upper page bit “y” and a lower page bit “x”, a flag for each storage element may be generated as flag=(upper page bit) XOR (lower page bit). Other examples include flag=(lower page bit), flag=(NOT (upper page bit)) AND (lower page bit), or flag=(upper page bit) OR (lower page bit).

During operation, a write request 133 may be received from the host device 130. The host device 130 may send the user data 132 in a logical address sequence as the first page 171, the second page 172, the third page 173, and the fourth page 174. The write order engine 122 may select a writing order for the received user data 132, such as the first order 126 or the second order 128.

If the selected writing order is the first order 126, the write order engine 122 may re-order the user data 132 by sending a sequence of write commands to the memory die 103 so that the user data 132 is stored so that pages with lower LBAs are at word lines having higher physical addresses and pages with higher LBAs are at word lines having lower physical addresses, as described in further detail below. The control circuitry 164 may cause the write circuitry 108 to process the received write commands.

After storing the user data 132, the data storage device 102 may receive a read request 134 from the host device 130 that indicates a sequence of LBAs to be read, matching the LBA order of LBA 1, LBA 2, LBA 3, and LBA 4. In response to the read request 134, the data storage device 102 may retrieve data from the non-volatile memory 104 and may provide resulting data 132 to the host device 130 as the sequentially requested pages 171-174.

The controller 120 may access the write order flags 190 to determine whether the user data 132 stored at the first block 140 is stored according to the first order 126 or the second order 128. In response to determining that the user data 132 in the first block 140 is stored according to the first order 126, the controller 120 may issue a first read command to read the lower page 158 and the upper page 159 without using DLA mode, to return the read data (the first page 171 and the second page 172) to the host device 130. Alternatively, if WL1 152 is not the highest addressed word line in the first block 140, a next word line (e.g., WL2 (not shown)) may be sensed to populate the DLA flag latch 160, followed by reading WL1 152 using DLA mode.

The data read from the second word line WL1 152 is also processed to generate DLA flag data. For example, the data read from the second word line WL1 152 may be stored within the data latches 162. After storing the data from the second word line WL1 152 in the data latches 162, the data may be processed to generate DLA flags. For example, a logical operation may be applied to each value (e.g., a pair of bits corresponding to each MLC cell value) stored within the data latches 162, to determine whether the corresponding storage element has a threshold voltage that is defined as a “high” voltage value or as a “low” voltage value. Values that are indicated as corresponding to a high voltage may be designated with a logic “1” value (e.g., a flag set to “1”), and values that correspond to a low voltage may be designated with a logic “0” value (e.g., a flag set to “0”). Thus, the data read from the second word line WL1 152 and stored within the data latches 162 may be processed in order to generate DLA flag data. Each DLA flag corresponds to a particular cell within the non-volatile memory 104 and indicates whether that particular cell stores a high voltage value (e.g., flag value of “1”) or a low voltage value (e.g., flag value of “0”). The generated flag data (e.g., binary data) may be written to the DLA flag latch 160. Thus, the DLA flag latch 160 includes a plurality of flags (e.g., a plurality of bits), where each bit indicates a high voltage value or a low voltage value corresponding to a respective cell within a word line (e.g. the second word line 152 (WL1)).

After the flags have been stored in the DLA flag latch 160, the third page 173 and the fourth page 174 are read from WL0 using the DLA mode. To illustrate, the third page 173 (e.g., the lower page 156) may be read at a first time, while applying a first voltage to the second word line 152 to generate first sense data. Thereafter, the third page 173 is read, at a second time, while applying a second voltage to the second word line 152 to generate second sense data. For example, the third page 173 may be read (at a first time) while applying the first voltage 112 to the second word line 152 to generate first sense data, and subsequently, the third page 173 may be read (at a second time) while applying the second voltage 114 to the second word line 152 to generate second sense data. Depending on the value of the flags stored within the DLA flag latch 160, either the first sense data or the second sense data, for each cell of the first word line 150, is selected to determine first page data. For example, if a flag corresponding to a particular cell within a word line indicates a high voltage value then the first sensed data corresponding to reading the lower page 156 while applying the high voltage value (e.g., V1 (112)) to the second word line 152 is used. Alternatively, if the flag within the DLA flag latch 160 corresponds to a low voltage value, then the second sensed data resulting from reading the lower page 156 while applying the lower voltage (e.g. the voltage V2 (114)) to the second word line 152 is used. Once the third page 173 has been determined, the third page 173 is provided to the host device 130. The fourth page 174 may be read from the upper page 157 of the first word line 150 in a similar manner as described with respect to the third page 173.

By storing sequential data according to the first order 126, reading the sequential data using DLA mode reduces a number of times a word line is read by using data that is read responsive to a first request to populate the DLA flag latch 160. The DLA flag latch 160 is then used when reading data responsive to a next sequential request. Reading the data and populating the DLA flag latch 160 for a next read may be accomplished using a single reading of the word line, as compared to reading the word line responsive to a data request and reading the word line again to generate DLA flag data for a neighboring word line. Thus, access time using the above-described method is improved at least partially as a result of a reduced number of reads of each word line.

Although operation of the data storage device 102 is described with respect to storing and retrieving the user data 132, it should be understood that the controller 120 is configured to write data to at least some of the blocks 140-144 in a way that improves read efficiency when reading pages from the blocks sequentially. The pages of a block may be re-ordered at write time into a non-sequential order, but may be read in a fully sequential order when the data is requested sequentially. Because pages may be read in sequential order while reading in DLA mode as described above, the controller 120 can send the read data to the host device 130 in the order the data is read from the non-volatile memory 104 without the controller 120 re-ordering the data at read time.

Table 1 illustrates an “optimal” order of pages for sequential reading using DLA mode as described with respect to FIG. 1. Although the example of Table 1 corresponds to a 2-bit per cell (2-BPC) MLC implementation in a block having four word lines, the systems and methods of the present disclosure are applicable to blocks with any number of word lines.

TABLE 1

| | Lower Pages | Upper Pages |
|---|---|---|
| Word Line 3 | Page 0 | Page 1 |
| Word Line 2 | Page 2 | Page 3 |
| Word Line 1 | Page 4 | Page 5 |
| Word Line 0 | Page 6 | Page 7 |

An “optimal” reading sequence of the data order illustrated in Table 1 can avoid duplicate reads in DLA mode to improve DLA efficiency, as provided in the following example.

1. The controller 120 sends “read page 0” command

2. The memory die 103 senses word line 3 lower page once (DLA may not be used when reading the last word line (i.e., the word line with the highest word line physical address in the block))

3. The controller 120 reads out page 0 data (and the memory die 103 keeps a copy in the data latches 162)

4. The controller 120 sends “read page 1” command

5. The memory die 103 senses word line 3 upper page once

6. The controller 120 reads out page 1 data (and the memory die 103 keeps a copy in the data latches 162)

7. Word line 3 data (pages 0 and 1) is processed to generate the DLA flags which are moved to the DLA flag latch 160

8. The controller 120 sends “read page 2” command

9. The memory die 103 senses word line 2 lower page twice, selecting a sensing result for each cell according to its corresponding DLA flag

10. The controller 120 reads out page 2 data (and the memory die 103 keeps a copy in the data latches 162)

11. The controller 120 sends “read page 3” command

12. The memory die 103 senses word line 2 upper page twice, selecting a sensing result for each cell according to its corresponding DLA flag

13. The controller 120 reads out page 3 data (and the memory die 103 keeps a copy in the data latches 162)

14. Word line 2 data (pages 2 and 3) is processed to generate the DLA flags which are moved to the DLA flag latch 160

15. The controller 120 sends “read page 4” command

16. The memory die 103 senses word line 1 lower page twice, selecting a sensing result for each cell according to its corresponding DLA flag

17. The controller 120 reads out page 4 data (and the memory die 103 keeps a copy in the data latches 162)

18. The controller 120 sends “read page 5” command

19. The memory die 103 senses word line 1 upper page twice, selecting a sensing result for each cell according to its corresponding DLA flag

20. The controller 120 reads out page 5 data (and the memory die 103 keeps a copy in the data latches 162)

21. Word line 1 data (pages 4 and 5) is processed to generate the DLA flags which are moved to the DLA flag latch 160

22. The controller 120 sends “read page 6” command

23. The memory die 103 senses word line 0 lower page twice, selecting a sensing result for each cell according to its corresponding DLA flag

24. The controller 120 reads out page 6

25. The controller 120 sends “read page 7” command

26. The memory die 103 senses word line 0 upper page twice, selecting a sensing a result for each cell according to its corresponding DLA flag

27. The controller 120 reads out page 7

In the example above, every page is sensed only once in the sequence (and each word line is sensed twice, once for the lower page and once for the upper page at the word line), and the order of receiving the pages in the controller 120 is sequential (from lowest page number to highest page number) so that every page can be sent out by the controller 120 to the host device 130 upon arrival. No extra RAM buffering is required in the controller 130 for achieving “optimal” DLA efficiency.

The controller 120 may create the arrangement of pages illustrated in Table 1 when writing the pages to the block. A writing order, or sequence of write commands, may depend on the particular programming scheme used by the non-volatile memory 104. If the non-volatile memory programs word lines in order (from lowest physical word line address to highest physical word line address) then the following writing sequence of pages during write time may generate the arrangement of Table 1.
1. The controller 120 sends “write page 6” command
2. The controller 120 sends “write page 7” command
3. The controller 120 sends “write page 4” command
4. The controller 120 sends “write page 5” command
5. The controller 120 sends “write page 2” command
6. The controller 120 sends “write page 3” command
7. The controller 120 sends “write page 0” command
8. The controller 120 sends “write page 1” command

If the non-volatile memory 104 uses an out-of-order programming scheme, such as an “LM” programming scheme, the writing sequence may be adjusted to achieve the arrangement of Table 1. An example of a page programming sequence in an LM-type memory is depicted in Table 2.

TABLE 2

| | Lower Pages | Upper Pages |
|---|---|---|
| Word Line 3 | 6^{th} written page | 8^{th} written page |
| Word Line 2 | 4^{th} written page | 7^{th} written page |
| Word Line 1 | 2^{nd} written page | 5^{th} written page |
| Word Line 0 | 1^{st} written page | 3^{rd} written page |

The writing sequence of pages during write time for generating the arrangement of Table I when using the LM writing order of Table 2 is:
1. The controller 120 sends “write page 6” command
2. The controller 120 sends “write page 4” command
3. The controller 120 sends “write page 7” command
4. The controller 120 sends “write page 2” command
5. The controller 120 sends “write page 5” command
6. The controller 120 sends “write page 0” command
7. The controller 120 sends “write page 3” command
8. The controller 120 sends “write page 1” command

Using LM mode in a 2 BPC implementation, the page writing order to achieve the arrangement of Table 1 for a four-line block is denoted as {6, 4, 7, 2, 5, 0, 3, 1}. The following pseudo-code corresponds to a generalized page writing order for blocks with any number of word lines.

N = numberOfPagesInBlock
lowerPage = N−2
Send “write page #lowerPage” command
lowerPage = lowerPage − 2
Send “write page #lowerPage” command
upperPage = N−1
Send “write page #upperPage” command
While (lowerPage != 0) do {

lowerPage = lowerPage − 2
Send “write page #lowerPage” command
upperPage = upperPage − 2
Send “write page #upperPage” command

}
Send “write page 1” command

The “optimal” DLA arrangement of pages of Table 1 is not the only “optimal” DLA arrangement. Table 3 illustrates another DLA “optimal” arrangement.

TABLE 3

| | Lower Pages | Upper Pages |
|---|---|---|
| Word Line 3 | Page 1 | Page 0 |
| Word Line 2 | Page 3 | Page 2 |
| Word Line 1 | Page 5 | Page 4 |
| Word Line 0 | Page 7 | Page 6 |

Using the arrangement of Table 3, a reading sequence that is “optimal” in terms of DLA efficiency is:
1. The controller 120 sends “read page 0” command
2. The non-volatile memory 104 senses word line 3 upper page once (DLA not used in the “last” word line)
3. The controller 120 reads out page 0 data (and the data latches 162 store a copy)
4. The controller 120 sends “read page 1” command
5. The non-volatile memory 104 senses word line 3 lower page once (DLA not used in the “last” word line)
6. The controller 120 reads out page 1 data (and the data latches 162 store a copy)
7. Word line 3 data (pages 0 and 1) is processed to generate the DLA flags which are stored in the DLA flag latch 160
8. The controller 120 sends “read page 2” command
9. The non-volatile memory 104 senses word line 2 upper page twice, selecting a sensing result for each cell according to its corresponding DLA flag
10. The controller 120 reads out page 2 data (and the data latches 162 store a copy)
11. The controller 120 sends “read page 3” command
12. The non-volatile memory 104 senses word line 2 lower page twice, selecting a sensing result for each cell according to its corresponding DLA flag
13. The controller 120 reads out page 3 data (and the data latches 162 store a copy)
14. Word line 2 data (pages 2 and 3) is processed to generate the DLA flags which are stored in the DLA flag latch 160
15. The controller 120 sends “read page 4” command
16. The non-volatile memory 104 senses word line 1 upper page twice, selecting a sensing result for each cell according to its corresponding DLA flag
17. The controller 120 reads out page 4 data (and the data latches 162 store a copy)
18. The controller 120 sends “read page 5” command
19. The non-volatile memory 104 senses word line 1 lower page twice, selecting a sensing result for each cell according to its corresponding DLA flag
20. The controller 120 reads out page 5 data (and the data latches 162 store a copy)
21. Word line 1 data (pages 4 and 5) is processed to generate the DLA flags which are stored in the DLA flag latch 160
22. The controller 120 sends “read page 6” command
23. The non-volatile memory 104 senses word line 0 upper page twice, selecting a sensing result for each cell according to its corresponding DLA flag
24. The controller 120 reads out page 6
25. The controller 120 sends “read page 7” command
26. The non-volatile memory 104 senses word line 0 lower page twice, selecting a sensing result for each cell according to its corresponding DLA flag
27. The controller 120 reads out page 7

A writing order for a non-LM block using the arrangement of Table 3 is:
1. The controller 120 sends “write page 7” command
2. The controller 120 sends “write page 6” command
3. The controller 120 sends “write page 5” command
4. The controller 120 sends “write page 4” command
5. The controller 120 sends “write page 3” command
6. The controller 120 sends “write page 2” command
7. The controller 120 sends “write page 1” command
8. The controller 120 sends “write page 0” command

This order is opposite of the “natural” order. In other words, in this case, the controller 120 may write the pages exactly in reverse order.

A writing order for an LM block for achieving the arrangement of Table 3 is:
1. The controller 120 sends “write page 7” command
2. The controller 120 sends “write page 5” command
3. The controller 120 sends “write page 6” command
4. The controller 120 sends “write page 3” command
5. The controller 120 sends “write page 4” command
6. The controller 120 sends “write page 1” command
7. The controller 120 sends “write page 2” command
8. The controller 120 sends “write page 0” command

The following pseudo-code generalizes the above LM arrangement writing order to blocks with any number of word lines:

N = numberOfPagesInBlock
lowerPage = N−1
Send “write page #lowerPage” command
lowerPage = lowerPage − 2
Send “write page #lowerPage” command
upperPage = N−2
Send “write page #upperPage” command
While (lowerPage != 1) do {

lowerPage = lowerPage − 2
Send “write page #lowerPage” command
upperPage = upperPage − 2
Send “write page #upperPage” command

}
Send “write page 0” command

The arrangements depicted in Table 1 and Table 3 are not the only “optimal” DLA block arrangements. Every word line of a block may store either a {page i, page i+1} arrangement or a {page i+1, page i} arrangement without disturbing the DLA-optimality of the block arrangement. Each word line arrangement can be determined independently of all other word lines. The number of DLA-optimal block arrangements is 2^{WL}, where WL is the number of word lines in a block. For each of these 2^{WL} arrangements there is a unique corresponding non-LM writing order and a unique corresponding LM writing order.

From a DLA-optimality point of view, all of the 2^{WL} possible optimal block arrangements are equally optimal. However, the arrangement of Table 1 and Table 3 may be less complex to implement because the repeating pattern of each word lines' pages facilitates simplified code for the writing sequence logic and for the reading sequence logic. Although theoretically the arrangements of Table 1 and Table 3 are effectively equivalent, actual implementations of the arrangements of Table 1 and Table 3 may differ in terms of complexity, cost, and/or one or more other factors.

Although described with respect to a 2-BPC implementation, the above principles may also apply to a 3-BPC implementation that uses DLA. In a 3-BPC implementation the “optimal” writing order depends on which page arrangements within the word lines are selected out of the (3!)^{WL}=6^{WL} alternative optimal block arrangements that are available and also depends on the programming plan that is implemented (e.g., linear, foggy-fine, etc.).

Any extra time overhead for a controller to write a block in a non-sequential order (as compared to writing the block in a default sequential order) may be negligible as compared to an overall writing duration. Flash writing operations may have durations on the order of hundreds or thousands of microseconds, while determining the number of the next page to write may be performed at a processor in the controller in nanoseconds. For example, an implementation may use the repeating pattern of the writing sequence (as shown above with pseudo-code for the arrangements of Table 1 and Table 3) or may use a look-up table that translates a “natural” or default sequential order into a DLA-optimal non-sequential order. Latency corresponding to a determination of a next page to write may be negligible as compared to the overall block writing time. Therefore, methods described in the present disclosure may be used to enhance reading performance with no detectable penalty (or very little penalty) to writing performance.

The data storage device 102 may implement a “block-based flash management system” in which a logical-to-physical address mapping employed by the data storage device 102 has the property that the mapping operation maps block-sized logical entities to block-sized physical entities. Determination of page addresses within a block is performed by other means and not by the logical-to-physical mapping table. For example, the physical page address within a physical block may be determined by a pre-defined rule, such as the physical page number is equal to the logical page number within the logical block. An implication of that property is that all of the physical pages sharing a common physical block have logical addresses (the addresses seen by the host) that are adjacent to each other in the logical address space and there are no gaps in-between. Similar operation may be implemented in a meta-block based management system that uses a block-based system that maps meta-block-sized logical entities to meta-block-sized physical entities. (A meta-block may be formed of multiple blocks located in different memory planes or memory dies that are processed together as if they were a single large block).

In addition to a main area of memory, the non-volatile memory 104 may include a caching or buffering area (e.g., “binary cache”, “update area”, “intermediate storage”, etc.) to cache or to buffer an input stream coming from the host device 130. Such caching or buffering enables the controller 120 to control timing and an order of copying newly arrived data from the buffer area into the main area. Incoming data may be first stored in such a buffer area. If there is insufficient free capacity in the buffer area, some “cleaning” activity may be performed. For example, a portion of the data in the buffer area can be moved into the main area to make room in the buffer area to receive the new data. During continued operation, this new data becomes “older data” and may also be moved into the main area to make room for newer data.

It is also possible for data to be moved into the main area without being written twice (i.e., without being written first to the buffer area and being written later to the main area). This may happen, for example, when the incoming data is “nicely arranged” (e.g., the data is arranged sequentially in chunks that are integral multiples of the page size). Such nicely arranged data may be sequentially stored into a previously empty buffer block upon arrival. Once the buffer block is full, the buffer block may be tagged as “main area block”, thus moving that data from a buffer area to the main area without actually writing the data again. This example provides an illustration of how physical boundaries between a buffer area and a main area of the non-volatile memory 104 need not be fixed and may dynamically change, with a physical block possibly moving between different areas (e.g., a block in a buffer area may be re-designated as being in a main area and/or a block in the main area may be re-designated as being in a buffer area one or more times over the life of the data storage device 102).

Clearing data from buffer areas into the main area may be performed as “background operations” (i.e., house-keeping operations performed when the non-volatile memory 104 is otherwise idle, with no host commands to serve). Clearing data from buffer areas during background operations may improve responsiveness of the data storage device 102 to future incoming data by increasing the likelihood that incoming data can be buffered without performing an intervening clearing operation to make room for the incoming data. Another common background operation is a “cleaning” activity of the main area itself. With time, a main area might become fragmented, resulting in reduced efficiency in handling certain types of operations as compared to an un-fragmented memory. Background cleaning of a main area may improve system performance and responsiveness.

In a block-based flash management implementation, for the data storage device 102 to be able to write a block in its main area in a DLA-optimal order, the data storage device 102 may require access to the full content of the block at the time the data storage device 102 starts writing the block. For example, the non-volatile memory 104 may only permit writing data to a block in sequential word line order. In such an example, the first word line that can be written in Block 1 140 is WL0 150. However, the DLA-optimal orders illustrated in Table 1 and Table 3 designates WL0 to contain the highest numbered pages (e.g., page 6 and page 7 in the four-word-line example of Table 1 and Table 3). In this example, the controller 120 should have access to the highest numbered pages to be written into a block when programming of the block begins to ensure the entire block can be written in a DLA-optimal arrangement.

In implementations where the data storage device 102 stores all incoming data into a buffering area prior to copying or moving the data from the buffering area to a destination block in the main area of the non-volatile memory 104, all of the data to be written into the destination block is already available, either in another block of the main area or in the buffer area.

However, some blocks of the main area may store incoming data without having all data available to the controller 120 at the time of writing. For example, the data storage device 120 may detect when a “nicely arranged” input stream of data is received and stored into a block of the buffer area. The data storage device 120 may designate the block as part of the main area without writing the data to a second block. As a result, the main area of the non-volatile memory 104 may include blocks that store data in a DLA-optimal arrangement and other blocks that do not store data in a DLA-optimal arrangement.

The data storage device 102 may be configured to change stored data in the non-volatile memory 104 from a non-DLA-optimal arrangement to a DLA-optimal arrangement. For example, the data storage device 102 may be configured to perform “cleaning” background operations on the main area to re-arrange data in a block of the main area. For example, the data storage device 102 may copy data from a block in the main area storing the data in a non-DLA optimal arrangement to another block in the main area. In this case the controller 120 may employ methods of the present disclosure to program the destination block to store the data in a DLA-optimal arrangement.

As another example, the data storage device 102 may be configured to perform a “cleaning” operation of a buffer area when buffered data is not “nicely arranged”. The data may be fully located in the buffer area (but not “nicely arranged”) or the data may be distributed and located partially in the main area and partially in the buffer area (or in multiple different buffer areas).

The controller 120 may use the write order flags 190 to track which blocks in the non-volatile memory 104 are DLA-optimized and which blocks in the non-volatile memory 104 are not DLA-optimized. Although the write order flags 190 are illustrated in a dedicated portion of the non-volatile memory 104, in other implementations each block 140-144 may have one or more bits of meta-data (e.g., in a block's “header”, “control data”, “management data” or a similar-named field) assigned as a write order flag indicating whether the block stores data in a DLA-optimal arrangement, such as whether the block was written using the first order 126 (e.g., DLA-optimal) or using the second order (e.g., non-DLA-optimal). The write order flag may be written at the time the full block is written. In order to avoid having to read meta-data from the block every time the block is accessed for reading, flags of multiple main area blocks may be combined into one condensed table (e.g., the write order flags 190) that is maintained by the controller 120 so that the table indicates the correct status of all blocks. The table can reside in the non-volatile memory 104 for non-volatile storage and may also be cached during an initialization period (e.g., during power-on) into a RAM that is accessible to the controller 120. A table of the write order flags 190 may be maintained in a manner similar to maintaining other memory management tables (e.g., tables of address mapping and tables of write/erase cycle counts).

When the controller 120 is to sequentially read data from a block (e.g., in response to the read request 134 indicating the sequential LBAs 181-184) the controller 120 may read the corresponding write order flag for the block storing the data to be read. If the write order flag indicates the block was written as DLA-optimal, the controller 120 may cause the requested pages to be read in sequential LBA order and using DLA mode, populating the DLA flag latch 160 using data from one word line for use when reading data from a next word line. If the write order flag indicates the block was not written as DLA-optimal, the controller 120 may read the block in non-sequential LBA order (in order to gain in DLA efficiency but requiring the controller 120 to re-order the read data prior to sending data to the host device 130) or the controller 120 may read the block sequentially using less efficient DLA methods.

In some implementations, the controller 120 may be configured to write one or more portions of a block according to an optimal DLA order (rather than writing the entire block in the optimal DLA order) and to read one or more portions of the block according to the optimal DLA order. For example, the controller 120 may implement a group-based flash management system in which logical-to-physical address mapping is performed to map logical groups of pages to physical groups of pages, where a group of pages includes more than a single page but less than a full block. In an implementation where the group size is equal to half of a block (or half of a meta-block, if meta-blocks are used), there are two groups per block. When writing of a block begins and not all data of the block is fully available, but the first group (e.g., the first half of the block) is fully available, the controller 120 may order the pages of the first half of the block, ignoring the ordering of the second half of the block. In this case the meta-data may contain multiple write order flags, including a first flag indicating a write order of the first half and a second flag indicating a write order of the second half.

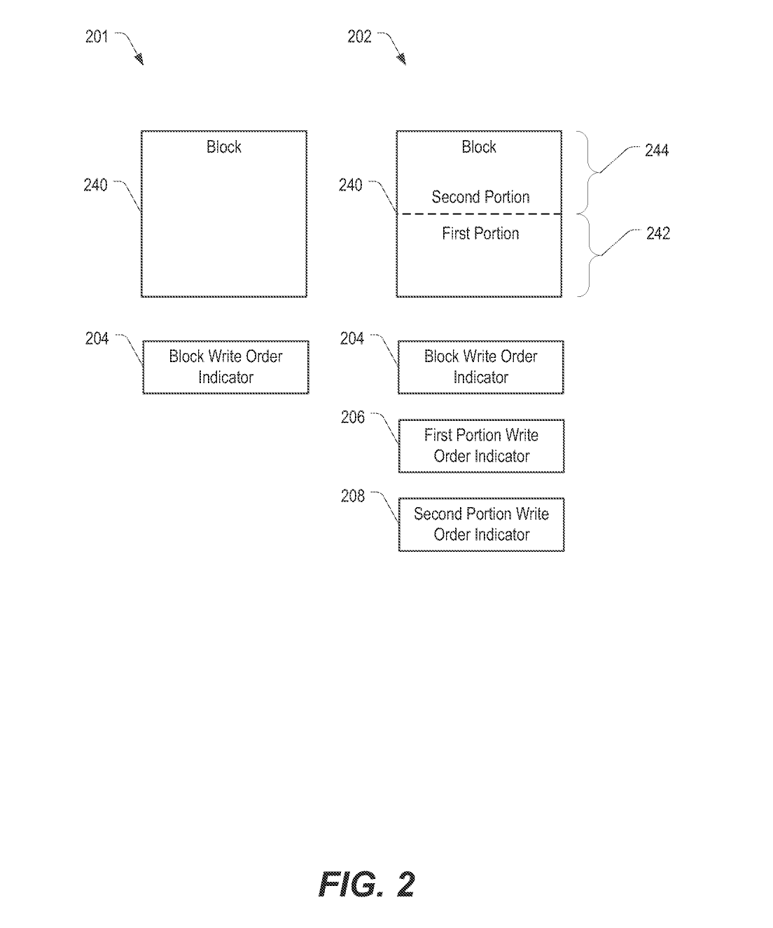

FIG. 2 illustrates a first embodiment 201 of a block 240 and a second embodiment 202 of the block 240. In the first embodiment 201, the entire block 240 is written according to a DLA-optimal write order (e.g., the first order 126 of FIG. 1) or is written according to a non-DLA-optimal write order (e.g., the second order 128 of FIG. 1). A block write order indicator 204 indicates whether the block 240 is written according to the DLA-optimal write order (or alternatively, indicates which write order 126, 128 was used to store data to the block 240). In an implementation where only two write orders are supported by a data storage device (e.g., the first order 126 and the second order 128), the block write order indicator may be a single bit.

In the second embodiment 202, the block 240 has a first portion 242 that may be written according to a DLA-optimal write order (e.g., the first order 126 of FIG. 1) or that may be written according to a non-DLA-optimal write order (e.g., the second order 128 of FIG. 1). The block 240 has a second portion 244 that may be written according to a DLA-optimal write order (e.g., the first order 126 of FIG. 1) or that may be written according to a non-DLA-optimal write order (e.g., the second order 128 of FIG. 1) independently of the write order of the first portion 242. A first portion write order indicator 206 may indicate a first writing order that was used when writing the first portion 242 (e.g., DLA-optimal or non-DLA-optimal) and a second portion write order indicator 208 may indicate a second writing order that was used when writing the second portion 242. Each of the portion write order indicators 206 and 208 may be a single bit. Optionally, the write order indicator 204 may indicate order of the whole block 240 as a unit. For example, the write order indicator 204 may be a flag value indicating whether a first set of word lines in the first portion 242 and a second set of word lines in the second portion 244 are written using the same writing order. Alternatively, the write order indicator 204 may be a flag value indicating whether the whole block is written using a DLA-optimal order. In some implementations, if the write order indicator 204 is set, the other indicators 206, 208 are also set.

In an implementation of the data storage device 102 that uses the second embodiment 202, prior to the controller 120 reading the full block 240 sequentially the controller 120 may examine the corresponding flags (indicators 204-208) and act according to the following logic. If the block write order indicator 204 indicates a DLA-optimal order (e.g., the first order 128), the controller 120 may read the whole block 240 sequentially as described above. Otherwise, if the first portion block write indicator 206 corresponding to the first portion 242 indicates a DLA-optimal order, the controller 120 may read the first portion 242 sequentially, otherwise the controller 120 may read the first portion 242 either non-sequentially or according to non-optimal DLA methods. Additionally, if the second portion block write indicator 208 corresponding to the second portion 244 indicates a DLA-optimal order, the controller 120 may read the second portion 244 sequentially, otherwise the controller 120 may read the second portion 244 either non-sequentially or according to non-optimal DLA methods.

As another example, when the controller 120 is to read only one half (e.g., the first portion 242 or the second portion 244) of the block 240 sequentially, the controller 120 may examine only the corresponding one-half flag (e.g., the corresponding portion write order indicator 206 or 208) and read the half-block portion according to the flag value.

There are other arrangements of the half-block flags that may have equivalent functionality. For example, if the full-block indicator 204 is set the value of the other two indicators 206 and 208 may be ignored. As another example, instead of using flags corresponding to groups of pages, a flag can be assigned for each page to indicate whether the page can benefit from DLA reading. Such equivalent arrangements are within the scope of the present disclosure.

Similarly, the present disclosure is not limited to full-block or half-block groups. Any other size group may be implemented. As an illustrative example, blocks may be logically partitioned into four groups, each group is a quarter of a block, and each group may have a corresponding flag bit or write order indicator. Also, higher level flags may be used to indicate write order of the full block and of each of the half blocks.

The above methods are useful in block-based flash management systems because the nature of block-based flash management provides opportunities for writing blocks in a DLA-optimal order. A number of blocks that may store data in a DLA-optimal order may be dependent on the host's usage of the data storage device and may be dependent on specific processes used by the flash management system. In a usage scenario with relatively random writing by the host it is expected that a significant portion of the blocks may be put into a DLA-optimal order for enhanced performance during read operations.

In addition to the block-based and group-based implementations described above, techniques of the present disclosure may be applied to page-based flash memory systems where the logical-to-physical address mapping employed by the system has the property that the mapping operation maps page-sized (or portion-of-a-page-sized) logical entities to page-sized (or portion-of-a-page-sized) physical entities. An implication of that property is that in such system there are in general no restrictions on the relative location of pages. For example, two logical pages sharing a common logical block may be mapped to two physical pages located in different physical blocks, and two logical pages located in two different logical blocks may be mapped to two physical pages sharing a common physical block.

In such systems most physical blocks contain pages corresponding to different logical blocks, thus reducing the probability of sequentially reading pages of data from a single block. In a page-based management implementation of the data storage device 102 of FIG. 1, the controller 120 may bring some blocks into DLA-optimal order and re-arrange content of one or more blocks to contain pages of a same logical block during main area cleaning and/or during buffer area cleaning. For example, data may be identified as likely to be read in sequential order and as providing a predicted efficiency gain for enhanced DLA reading due to data re-arranging and re-ordering that exceeds a cost in performance and power consumption to perform the data re-arranging and re-ordering.

FIG. 3 illustrates a particular embodiment of a method 300 of storing data. The method 300 may be performed in a memory device including a controller and a non-volatile memory, such as the data storage device 102 of FIG. 1.

A writing order is selected for data to be written to a set of word lines of a block of the non-volatile memory, at 302. The data is organized in pages that are ordered according to a logical page address order. The writing order is selected from at least a first order or a second order that is distinct from the first order. Stored data in the non-volatile memory written according to the first order has logical page addresses that decrease with increasing values of word line physical addresses. For example, the write order selector 122 of FIG. 1 may select the first order 126 or the second order 128. Data stored in the non-volatile memory 104 that is written according to the first order 126 has logical page addresses that decrease with increasing values of word line physical addresses, such as the user data 132 that decreases from LBA 3 183 and LBA 4 184, stored at WL0 150, to LBA 1 and LBA 2, stored at WL1 152. Stored data in the non-volatile memory written according to the second order, such as the second order 128, may have logical page addresses that increase with increasing values of word line physical addresses.

The data is written to the set of word lines according to the selected writing order, at 304. For example, the first order may be selected at least partially based on whether a page of the data having the highest logical page address of the pages to be stored in the set of word lines is available to the controller when the writing order is selected. As another example, the data may be written during a background operation that includes reading the data from one or more other blocks of the memory and writing the data according to the selected writing order. The block may also include a second set of word lines that are programmable according to a second selected writing order. For example, the block may correspond to the block 240 of FIG. 2 having a first set of word lines in the first portion 242 and a second set of word lines in the second portion 244.

A flag value that indicates the selected writing order is stored, at 306. For example, the flag value may be stored in the write order flags 190 of FIG. 1 and/or may correspond to one or more of the write order indicators 204-208 of FIG. 2.

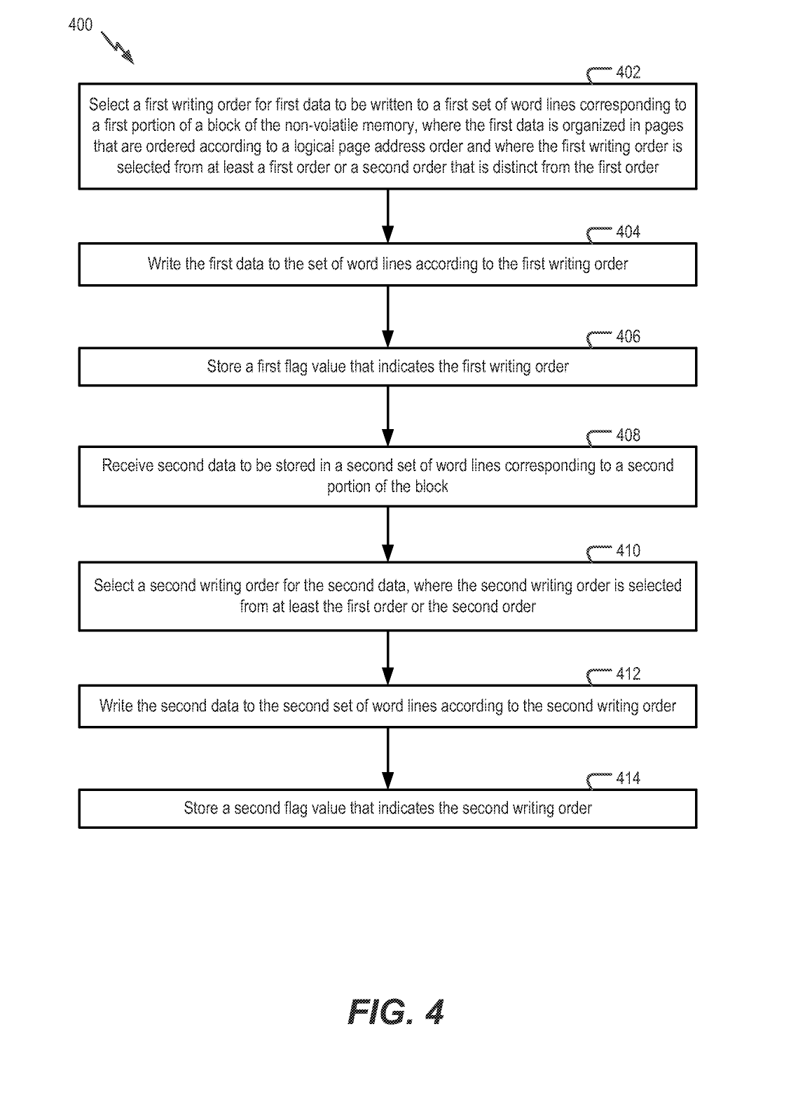

FIG. 4 illustrates another particular embodiment of a method 400 of storing data. The method 400 may be performed in a memory device including a controller and a non-volatile memory, such as the data storage device 102 of FIG. 1.

A first writing order is selected for first data to be written to a first set of word lines corresponding to a first portion of a block of the non-volatile memory, at 402. For example, the first set of word lines corresponding to the first portion of the block may correspond to the first portion 242 of FIG. 2. The first data is organized in pages that are ordered according to a logical page address order, such as LBAs 1-4 of the user data 132 of FIG. 1. The first writing order is selected from at least a first order or a second order that is distinct from the first order, such as the first order 126 and the second order 128 of FIG. 1.

The first data is written to the set of word lines according to the first writing order, at 404, and a first flag value that indicates the first writing order is stored, at 406. For example, the first flag value may correspond to the first portion write order indicator 206 of FIG. 2 and may be stored as part of the write order flags 190 of FIG. 1.

Second data may be received to be stored in a second set of word lines corresponding to a second portion of the block, at 408. For example, the second set of word lines corresponding to the second portion of the block may correspond to the second portion 244 of FIG. 2. A second writing order is selected for the second data, at 410. The second writing order is selected from at least the first order or the second order, such as from the first order 126 or the second order 128 of FIG. 1.

The second data is written to the second set of word lines according to the second writing order, at 412, and a second flag value that indicates the second writing order is stored, at 414. For example, the second flag value may correspond to the second portion write order indicator 208 of FIG. 2 and may be stored as part of the write order flags 190 of FIG. 1. In some implementations, a third flag value indicating whether the first set of word lines and the second set of word lines are written using the same writing order, such as the block write order indicator 240 of FIG. 2, may also be stored.

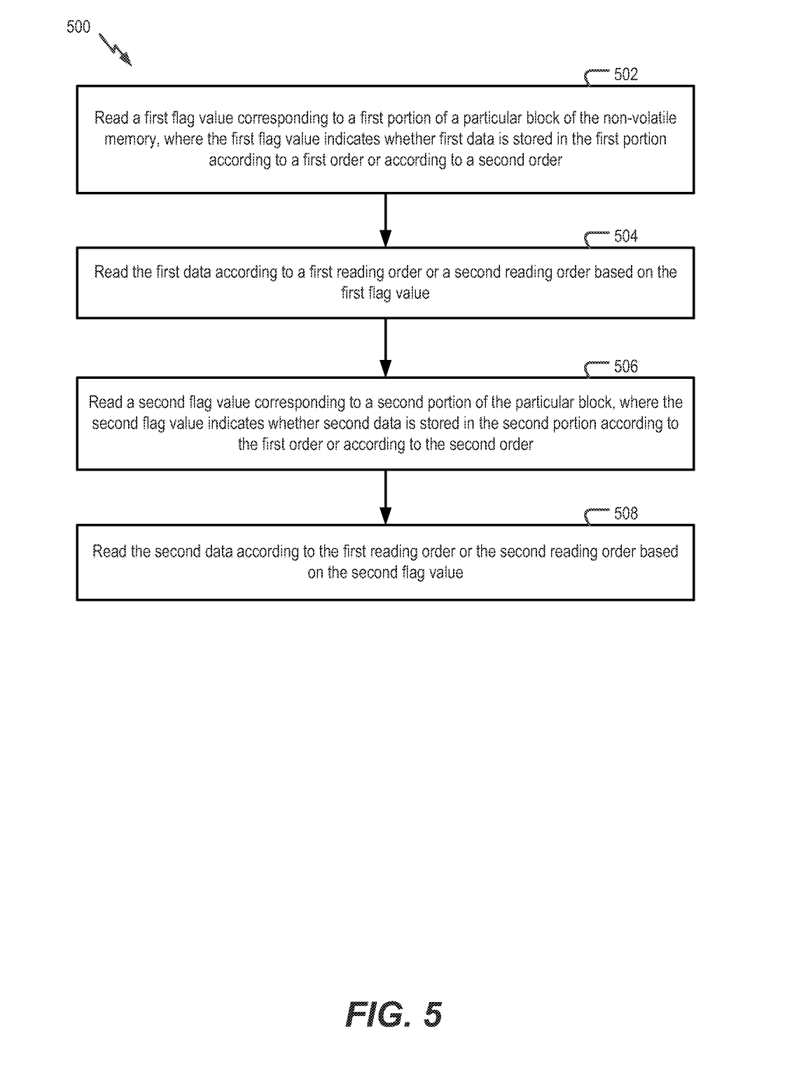

FIG. 5 illustrates another particular embodiment of a method 500 of storing data. The method 500 may be performed in a memory device including a controller and a non-volatile memory, such as the data storage device 102 of FIG. 1.

A first flag value corresponding to a first portion of a particular block of the non-volatile memory is read, at 502. The first flag value indicates whether first data is stored in the first portion according to a first order or according to a second order. For example, the controller 120 of FIG. 1 can read the first flag value from the write order flags 190 in the non-volatile memory 104 or from a copy of the write order flags 190 stored in controller RAM. The first flag value may correspond to the first portion write order indicator 206 of FIG. 2.

The first data is read according to a first reading order or a second reading order based on the first flag value, at 404. The first order may correspond to logical page addresses that decrease with increasing values of word line physical addresses, and the first reading order may correspond to sensing word lines in order of decreasing word line physical addresses. The second order may correspond to logical page addresses that increase with increasing values of word line physical addresses, and the second reading order may correspond to sensing word lines in order of increasing word line physical addresses.

To illustrate, when the first order 126 corresponds to a DLA-optimal arrangement of stored data such as in Table 1 or Table 3, the first reading order may include reading upper and lower pages from the word line having the highest word line physical address (e.g., Word Line 3 in Table 1), followed by reading upper and lower pages from the word line having the second highest word line physical address (e.g., Word Line 2 in Table 1), continuing to reading sequentially lower-addressed word lines (e.g., Word Line 1, Word Line 0 in Table 1). When the second order 128 corresponds to a non-DLA-optimal arrangement of stored data, the second reading order may include reading upper and lower pages from the word line having the lowest word line physical address (e.g., Word Line 0 in Table 1), followed by sequentially increasing word line physical addresses (e.g., Word Line 1, Word Line 2, and Word Line 3).

A second flag value corresponding to a second portion of the particular block is read, at 506. The second flag value indicates whether second data is stored in the second portion according to the first order or according to the second order. For example, the controller 120 of FIG. 1 can read the second flag value from the write order flags 190 in the non-volatile memory 104 or from a copy of the write order flags 190 stored in controller RAM. The second flag value may correspond to the second portion write order indicator 208 of FIG. 2. The second data is read according to the first reading order or the second reading order based on the second flag value, at 508.

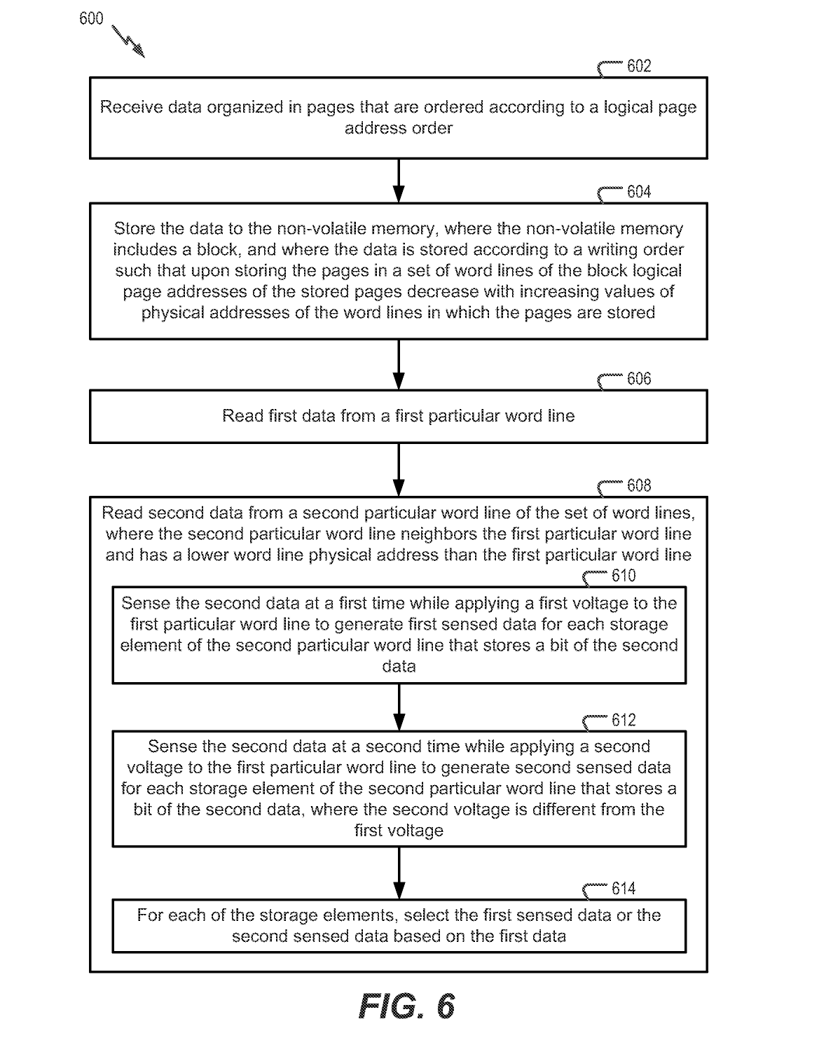

FIG. 6 illustrates another particular embodiment of a method 600 of storing data. The method 600 may be performed in a memory device including a controller and a non-volatile memory, such as the data storage device 102 of FIG. 1.

Data is received that is organized in pages that are ordered according to a logical page address order, at 602. For example, the data may correspond to the user data 132 of FIG. 1 that is ordered according to the LBAs 181-184.

The data is stored to the non-volatile memory, at 604. The non-volatile memory includes a block, such as the first block 140 of FIG. 1. The data is stored according to a writing order such that upon storing the pages in a set of word lines of the block logical page addresses of the stored pages decrease with increasing values of physical addresses of the word lines in which the pages are stored.

First data is read from a first particular word line, at 606, such as the lower page 158 and the upper page 159 of WL1 152. Second data is read from a second particular word line of the set of word lines, at 608. The second particular word line neighbors the first particular word line and has a lower word line physical address than the first particular word line, such as WL0 150.

Reading the second data includes sensing the second data at a first time while applying a first voltage (e.g., the first voltage 112) to the first particular word line to generate first sensed data for each storage element of the second particular word line that stores a bit of the second data, at 610. Reading the second data also includes sensing the second data at a second time while applying a second voltage (e.g., the second voltage 114) to the first particular word line to generate second sensed data for each storage element of the second particular word line that stores a bit of the second data, at 612. The second voltage is different from the first voltage.

For each of the storage elements, the first sensed data or the second sensed data is selected based on the first data, at 614. For example, reading the first data may include sensing the first particular word line and storing flags in a latch, such as the DLA flag latch 160. The flags may be set according to the sensing of the first particular word line. Each flag may correspond to a storage element of the second particular word line. Selecting the first sensed data or the second sensed data based on the first data may include selecting, for each storage element of the second particular word line, the first sensed data or the second sensed data based on a value of the corresponding flag in the latch.

Although various components depicted herein are illustrated as block components and described in general terms, such components may include one or more microprocessors, state machines, or other circuits configured to enable the data storage device 102 of FIG. 1 to reorder data to improve efficiency in performing DLA operations. For example, the controller 120 may represent physical components, such as hardware controllers, state machines, logic circuits, or other structures, to enable the data storage device 102 of FIG. 1 to reorder data to enhance DLA operations.

The controller 120 may be implemented using a microprocessor or microcontroller programmed to perform DLA operations as described herein. In a particular embodiment, the controller 120 includes a processor executing instructions that are stored at the non-volatile memory 104. Alternatively, or in addition, executable instructions that are executed by the processor may be stored at a separate memory location that is not part of the non-volatile memory 104, such as at a read-only memory (ROM).

In a particular embodiment, the data storage device 102 may be implemented in a portable device configured to be selectively coupled to one or more external devices. However, in other embodiments, the data storage device 102 may be attached or embedded within one or more host devices, such as within a housing of a host communication device. For example, the data storage device 102 may be within a packaged apparatus such as a wireless telephone, a personal digital assistant (PDA), a gaming device or console, a portable navigation device, or other device that uses internal non-volatile memory. In a particular embodiment, the data storage device 102 may include a non-volatile memory, such as a three-dimensional (3D) memory, a flash memory (e.g., NAND, NOR, Multi-Level Cell (MLC), a Divided bit-line NOR (DINOR) memory, an AND memory, a high capacitive coupling ratio (HiCR), asymmetrical contactless transistor (ACT), or other flash memories), an erasable programmable read-only memory (EPROM), an electrically-erasable programmable read-only memory (EEPROM), a read-only memory (ROM), a one-time programmable memory (OTP), or any other type of memory.

The illustrations of the embodiments described herein are intended to provide a general understanding of the various embodiments. Other embodiments may be utilized and derived from the disclosure, such that structural and logical substitutions and changes may be made without departing from the scope of the disclosure. This disclosure is intended to cover any and all subsequent adaptations or variations of various embodiments.

The above-disclosed subject matter is to be considered illustrative, and not restrictive, and the appended claims are intended to cover all such modifications, enhancements, and other embodiments, which fall within the scope of the present disclosure. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method comprising:
in a memory device including a controller and a non-volatile memory, performing:
selecting a writing order for data to be written to a set of word lines of a block of the non-volatile memory, wherein the data is organized in pages that are ordered according to a logical page address order, wherein the writing order is selected from at least a first order or a second order that is distinct from the first order, and wherein stored data in the non-volatile memory written according to the first order has logical page addresses that decrease with increasing values of word line physical addresses;
writing the data to the set of word lines according to the selected writing order; and
storing a flag value that indicates the selected writing order.

2. The method of claim 1, wherein the block further includes a second set of word lines that are programmable according to a second selected writing order.

3. The method of claim 1, wherein stored data in the non-volatile memory written according to the second order has logical page addresses that increase with increasing values of word line physical addresses.

4. The method of claim 1, wherein the first order is selected at least partially based on whether a page of the data having the highest logical page address of the pages to be stored in the set of word lines is available to the controller when the writing order is selected.

5. The method of claim 1, wherein the data is written during a background operation that includes reading the data from one or more other blocks of the memory and writing the data according to the selected writing order.

6. A method comprising:
in a memory device including a controller and a non-volatile memory, performing:
selecting a first writing order for first data to be written to a first set of word lines corresponding to a first portion of a block of the non-volatile memory, wherein the first data is organized in pages that are ordered according to a logical page address order and wherein the first writing order is selected from at least a first order or a second order that is distinct from the first order;
writing the first data to the set of word lines according to the first writing order;
storing a first flag value that indicates the first writing order;
selecting a second writing order for second data to be stored in a second set of word lines corresponding to a second portion of the block, wherein the second writing order is selected from at least the first order or the second order;
writing the second data to the second set of word lines according to the second writing order; and
storing a second flag value that indicates the second writing order.

7. The method of claim 6, further comprising storing a third flag value indicating whether the first set of word lines and the second set of word lines are written using the same writing order.

8. A method comprising:
in a memory device including a controller and a non-volatile memory, performing:
reading a first flag value corresponding to a first portion of a particular block of the non-volatile memory, wherein the first flag value indicates whether first data is stored in the first portion according to a first order or according to a second order;
reading the first data according to a first reading order or a second reading order based on the first flag value;
reading a second flag value corresponding to a second portion of the particular block, wherein the second flag value indicates whether second data is stored in the second portion according to the first order or according to the second order; and
reading the second data according to the first reading order or the second reading order based on the second flag value.

9. The method of claim 8, wherein the first order corresponds to logical page addresses that decrease with increasing values of word line physical addresses, and wherein the first reading order corresponds to sensing word lines in order of decreasing word line physical addresses.

10. The method of claim 9, wherein the second order corresponds to logical page addresses that increase with increasing values of word line physical addresses, and wherein the second reading order corresponds to sensing word lines in order of increasing word line physical addresses.

11. A method comprising:
in a memory device including a controller and a non-volatile memory, performing:
receiving data organized in pages that are ordered according to a logical page address order;
storing the data to the non-volatile memory, wherein the non-volatile memory includes a block, and wherein the data is stored according to a writing order such that upon storing the pages in a set of word lines of the block logical page addresses of the stored pages decrease with increasing values of physical addresses of the word lines in which the pages are stored;
reading first data from a first particular word line; and
reading second data from a second particular word line of the set of word lines, wherein the second particular word line neighbors the first particular word line and has a lower word line physical address than the first particular word line, and wherein reading the second data includes:
sensing the second data at a first time while applying a first voltage to the first particular word line to generate first sensed data for each storage element of the second particular word line that stores a bit of the second data;
sensing the second data at a second time while applying a second voltage to the first particular word line to generate second sensed data for each storage element of the second particular word line that stores a bit of the second data, wherein the second voltage is different from the first voltage; and
for each of the storage elements, selecting the first sensed data or the second sensed data based on the first data.

12. The method of claim 11, wherein reading the first data includes sensing the first particular word line and storing flags in a latch, wherein the flags are set according to the sensing of the first particular word line and wherein each flag corresponds to a storage element of the second particular word line, and wherein selecting the first sensed data or the second sensed data based on the first data includes selecting, for each storage element of the second particular word line, the first sensed data or the second sensed data based on a value of the corresponding flag in the latch.

13. A data storage device comprising:
a controller; and
a non-volatile memory,
wherein the controller is configured to select a writing order for data to be written to a set of word lines of a block of the non-volatile memory, the data organized in pages that are ordered according to a logical page address order, to instruct the non-volatile memory to write the first data to the set of word lines according to the selected writing order, and to store a flag value that indicates the selected writing order,
wherein the writing order is selected from at least a first order or a second order that is distinct from the first order, and
wherein stored data in the non-volatile memory written according to the first order has logical page addresses that decrease with increasing values of word line physical addresses.

14. The data storage device of claim 13, wherein the block further includes a second set of word lines that are programmable according to a second selected writing order.

15. The data storage device of claim 13, wherein stored data in the non-volatile memory written according to the second order has logical page addresses that increase with increasing values of word line physical addresses.

16. The data storage device of claim 13, wherein the controller is configured to select the first order at least partially based on whether a page of the data having the highest logical page address of the pages to be stored in the set of word lines is available to the controller when the writing order is selected.

17. The data storage device of claim 13, wherein the data is written during a background operation that includes reading the data from one or more other blocks of the non-volatile memory and writing the data according to the selected writing order.

18. A data storage device comprising:
a controller; and
a non-volatile memory,
wherein the controller is configured to select a first writing order for first data to be written to a first set of word lines corresponding to a first portion of a block of the non-volatile memory and to select a second writing order for second data to be written to a second set of word lines corresponding to a second portion of the block, wherein the first writing order and the second writing order are selected from at least a first order or a second order that is distinct from the first order, and
wherein the controller is further configured to store a first flag value that indicates the first writing order and a second flag value that indicates the second writing order.

19. The data storage device of claim 18, wherein the controller is further configured to store a third flag value indicating whether the first set of word lines and the second set of word lines are written using the same writing order.

20. A data storage device comprising:
a memory that includes multiple blocks; and
a controller, wherein the controller is configured to read a first flag value corresponding to a first portion of a particular block of the non-volatile memory, the first flag value indicating whether first data is stored in the first portion according to a first order or according to a second order, and wherein the controller is further configured to read a second flag value corresponding to a second portion of the particular block, the second flag value indicating whether second data is stored in the second portion according to the first order or according to the second order.

21. The data storage device of claim 20, wherein the first order corresponds to logical page addresses that decrease with increasing values of word line physical addresses, and wherein the first reading order corresponds to sensing word lines in order of decreasing word line physical addresses.

22. The data storage device of claim 21, wherein the second order corresponds to logical page addresses that increase with increasing values of word line physical addresses, and wherein the second reading order corresponds to sensing word lines in order of increasing word line physical addresses.

23. A data storage device comprising:
a controller; and
a non-volatile memory,
wherein the controller is configured to receive data organized in pages that are ordered according to a logical page address order and to store the data to the non-volatile memory, wherein the non-volatile memory includes a block, and wherein the data is stored according to a writing order such that upon storing the pages in a set of word lines of the block logical page addresses of the stored pages decrease with increasing values of physical addresses of the word lines in which the pages are stored,
wherein the controller is further configured to read first data from a first particular word line and to read second data from a second particular word line of the set of word lines, wherein the second particular word line neighbors the first particular word line and has a lower word line physical address than the first particular word line, and wherein reading the second data includes:
sensing the second data at a first time while applying a first voltage to the first particular word line to generate first sensed data for each storage element of the second particular word line that stores a bit of the second data;
sensing the second data at a second time while applying a second voltage to the first particular word line to generate second sensed data for each storage element of the second particular word line that stores a bit of the second data, wherein the second voltage is different from the first voltage; and
for each of the storage elements, selecting the first sensed data or the second sensed data based on the first data.

24. The data storage device of claim 23, wherein reading the first data includes sensing the first particular word line and storing flags in a latch, wherein the flags are set according to the sensing of the first particular word line and wherein each flag corresponds to a storage element of the second particular word line, and wherein selecting the first sensed data or the second sensed data based on the first data includes selecting, for each storage element of the second particular word line, the first sensed data or the second sensed data based on a value of the corresponding flag in the latch.
